(19) United States
(12) Patent Application Publication
(10) Pub. No.: US 2014/0252576 A1
(43) Pub. Date: Sep. 11, 2014

(54) Semiconductor Device and Manufacturing Method Thereof

(71) Applicants: Hisashi Tanie, Tokyo (JP); Hiroshi Shintani, Tokyo (JP); Naotaka Tanaka, Tokyo (JP)

(72) Inventors: Hisashi Tanie, Tokyo (JP); Hiroshi Shintani, Tokyo (JP); Naotaka Tanaka, Tokyo (JP)

(73) Assignee: Hitachi, Ltd., Chiyoda-ku, Tokyo (JP)

(21) Appl. No.: 14/354,091

(22) PCT Filed: Oct. 31, 2011
(86) PCT No.: PCT/JP2011/075073

§ 371 Date: Apr. 24, 2014

(51) Int. Cl. H01L 23/00; H01L 21/52

(52) U.S. Cl. CPC H01L 23/562; H01L 21/52
USPC 257/669; 438/117

(57) ABSTRACT

A semiconductor device has a packaging structure in which a top surface of a semiconductor chip 1 is electrically connected to a conductive member 4 through a deformation absorption layer 2a and a joining layer 3a and a bottom surface thereof is electrically connected to a conductive member 5 through a deformation absorption layer 2b and a joining layer 3b. Each of the deformation absorption layers 2a and 2b includes a nano-structure layer 7 arranged at a center of a thickness direction and plate layers 6 and 8 of two layers with the nano-structure layer 7 therebetween. The nano-structure layer 7 has a structure in which a plurality of nano-structures 9 having a size of 1 μm or less are two-dimensionally arranged and thermal stress due to a thermal deformation difference of each member forming the semiconductor device is absorbed by deformation of the nano-structures 9.

### TECHNICAL FIELD

The present invention relates to technology that is effectively applied to reduction of thermal stress and improvement of heat radiation in a semiconductor device including a substrate and a semiconductor chip packaged on the substrate.

### BACKGROUND ART

As the background art of a field of the present technology, there are PTL 1 (JP-A-2006-287091), PTL 2 (JP-A-2003-188209), PTL 3 (JP-A-2003-298012), and NPL 1.

In PTL 1, as a solution to a problem “to prevent thermal breakdown of a semiconductor element due to a high temperature and generation of circuit characteristics resulting from a high load and interlayer film cracking in a thermocompression bonding process in which a high temperature and a high load are applied, by adopting a joining process technique in which joining is carried out at a low temperature under a low load”, technology “in a semiconductor device including a semiconductor element 1 having metal bumps 3 formed on a plurality of pad electrode portions 2 and a packaging substrate 4 having wiring electrode portions 5, conductive elastic bodies 6 having conductivity and elasticity are formed on the wiring electrode portions 5 of the packaging substrate 4, the semiconductor element 1 is packaged on the packaging substrate 4 with the metal bumps 3 shoved into the conductive elastic bodies 6, and the metal bumps 3 and the wiring electrode portions 5 are electrically connected and fixed by an insulating junction layer 10” is described (refer to Abstract).

In PTL 2, as a solution to a problem “to provide a semiconductor device and a manufacturing method thereof suitable for suppressing deterioration of connection reliability by thermal stress due to a thermal expansion coefficient difference of a semiconductor chip and a substrate and realizing high density packaging”, technology “a minute conductive connecting portion of which a shape is controlled by a substrate processed finely and a patterning technique is formed to connect the semiconductor chip and the substrate. The semiconductor device has a structure in which an electrode pad of the semiconductor chip is connected to an electrode pad of the substrate through the conductive connecting portion having at least two bent portions and curved portions and an insulating sealing portion is sealed therebetween. The semiconductor device can alleviate the thermal stress by deforming the conductive connecting portion and the insulating sealing portion when the thermal stress is applied and improve connection reliability” is described.

In PTL 3, as a solution to a problem “to provide a semiconductor device and a manufacturing method thereof in which there are not restrictions on heat resistance of element materials to be connected, there are not deterioration of a function of the device and damages to elements due to stress, and there is not a short circuit of adjacent electrodes due to a contact of adjacent connecting portions”, technology “a solid-state imaging element 10 includes a scanning circuit portion 12, a photoelectric converting portion 14, a micro-spring 16, and a connecting layer 18. The micro-spring 16 has one end fixed on a pixel electrode 30 by a metal or the like and is formed in a shape of a tongue curved upward. The micro-spring 16 contacts an electrode 42 of the side of the photoelectric converting portion in a state in which the micro-spring 16 is compressed in an allowable range and electrically connects the pixel electrode 30 and the electrode 42 of the side of the photoelectric converting portion. The connecting layer 18 structurally connects the scanning circuit portion 12 and the photoelectric converting portion 14” is described.

In NPL 1, a dynamic characteristic and a manufacturing method of a nano-structure layer used in the present invention are described.

### CITATION LIST

### Patent Literature

PTL 1: JP-A-2006-287091
PTL 2: JP-A-2003-188209
PTL 3: JP-A-2003-298012

### Non-Patent Literature

NPL 1: Sumigawa T. et. al., Disappearance of stress singularity at interface edge due to anostructured thin film, Engineering Fracture Mechanics 75 (2008) 3073-3083

### SUMMARY OF INVENTION

### Technical Problem

In a structure in which the semiconductor chip is packaged on the substrate, because different materials are combined and used, this generates thermal stress due to a thermal deformation difference of each member by a temperature change. If a used temperature range is expanded by diversification of use environments of semiconductor products, the generated thermal stress increases. For this reason, to prevent deterioration of reliability of the semiconductor products due to the thermal stress becomes a problem.

In addition, when the semiconductor products are operated, the semiconductor chip generates heat. If the temperature of the generated heat increases by an increase of a packaging density, a temperature rise of the semiconductor chip becomes remarkable and the efficiency deterioration of the semiconductor chip by the temperature rise and the damage of the member by the thermal stress are concerned about. Therefore, in a semiconductor packaging structure, suppressing of the temperature rise, that is, improvement of heat radiation becomes a problem.

An object of the invention is to provide a semiconductor packaging structure capable of realizing reduction of thermal stress and improvement of heat radiation and a manufacturing method thereof.

The above and other objects and novel characteristics of the invention will be apparent from the description of the present specification and the accompanying drawings.

### Solution to Problem

An outline of the representative invention among the inventions disclosed in the present application can be simply described as follows.

A semiconductor device according to an aspect of the invention includes a substrate and a semiconductor chip packaged on the substrate and a structure layer formed by two-dimensionally arranging a plurality of structures having a cross-sectional shape of a diameter or a length of one side of less than 1 μm is provided between the semiconductor chip and the substrate.

### Advantageous Effects of Invention

Effects obtained by the representative invention among the inventions disclosed in the present application can be simply described as follows.

A thermal deformation difference of each member forming a semiconductor device is absorbed by deformation of structures, so that thermal stress of the semiconductor device can be decreased.

In addition, a structure layer in which a plurality of structures are two-dimensionally arranged is used, so that thermal resistance of the semiconductor device decreases and heat radiation can be improved.

### BRIEF DESCRIPTION OF DRAWINGS

FIG. 1(a) is a cross-sectional view of a semiconductor device to be a first embodiment of the present invention and FIG. 1(b) is an enlarged cross-sectional view illustrating a part of FIG. 1(a).

FIG. 2(a) is a cross-sectional view of a semiconductor device to be a comparative example of the present invention and FIG. 2(b) is an enlarged cross-sectional view illustrating a part of FIG. 2(a).

FIGS. 3(a) to 3(e) are overall views and end enlarged views illustrating a manufacturing method of a semiconductor device to be a first embodiment of the present invention.

FIGS. 4(a) and 4(b) are cross-sectional views illustrating a manufacturing method of a semiconductor device following FIGS. 3(a) to 3(e).

FIGS. 5(a), 5(b), and 5(c) are diagrams illustrating effects of a semiconductor device to be a first embodiment.

FIGS. 6(a) and 6(b) are diagrams illustrating deformation and stress generated in a nano-structure according to a first embodiment.

FIG. 7 is a graph illustrating a relation of a shear displacement amount and maximum stress of a nano-structure obtained from a stress analysis.

FIG. 8 is a graph illustrating a relation of a shear displacement amount and maximum stress in a nano-structure having a height of 10 μm, acquired from a result of FIG. 7.

FIG. 9(a) is a plan view of a semiconductor device to be a second embodiment of the present invention, FIG. 9(b) is a cross-sectional view taken along the line A-A of FIG. 9(a), and FIG. 9(c) is an enlarged cross-sectional view of a part of FIG. 9(b).

FIG. 10(a) is a plan view of a semiconductor device to be a third embodiment of the present invention and FIG. 10(b) is a cross-sectional view taken along the line B-B of FIG. 10(b).

FIGS. 11(a), 11(b), and 11(c) are diagrams illustrating effects of semiconductor devices to be second and third embodiments.

FIG. 12 is a graph illustrating a result obtained by calculating a temperature change when a semiconductor chip repeats heat generation and a stop by a heat conduction analysis.

FIG. 13 is a graph illustrating temperature change amounts of a semiconductor device according to a comparative example and semiconductor devices according to second and third embodiments.

FIGS. 14(a) and 14(b) are plan views illustrating manufacturing methods of semiconductor devices to be second and third embodiments of the present invention and FIGS. 14(c), 14(d), and 14(e) are overall views and end enlarged views illustrating the manufacturing methods of the semiconductor devices to be the second and third embodiments of the present invention.

FIGS. 15(a) to 15(e) are overall views and end enlarged views illustrating manufacturing methods of semiconductor devices following FIGS. 14(a) to 14(e).

FIGS. 16(a) and 16(b) are cross-sectional views illustrating manufacturing methods of semiconductor devices following FIGS. 15(a) to 15(e).

FIG. 17(a) is a plan view of a semiconductor device to be a fourth embodiment of the present invention and FIG. 17(b) is a cross-sectional view taken along the line C-C of FIG. 17(a).

FIG. 18 is a cross-sectional view of a nano-structure layer used in a first embodiment of the present invention.

FIG. 19 is a cross-sectional view of a nano-structure layer used in a fifth embodiment of the present invention.

FIG. 20 is a cross-sectional view of a nano-structure layer used in a sixth embodiment of the present invention.

FIG. 21 is a cross-sectional view of a nano-structure layer used in a seventh embodiment of the present invention.

FIGS. 22(a), 22(b), and 22(c) are overall views and end enlarged views illustrating a manufacturing method of a nano-structure layer used in a seventh embodiment of the present invention.

FIG. 23 is a cross-sectional view of a nano-structure layer used in an eighth embodiment of the present invention.

FIGS. 24(a) to 24(d) are overall views and end enlarged views illustrating a manufacturing method of a nano-structure layer used in an eighth embodiment of the present invention.

FIG. 25 is a cross-sectional view of a nano-structure layer used in a ninth embodiment of the present invention.

FIG. 26(a) is a cross-sectional view of a semiconductor device to be a tenth embodiment of the present invention and FIG. 26(b) is an enlarged cross-sectional view illustrating a part of FIG. 26(a).

### DESCRIPTION OF EMBODIMENTS

Hereinafter, embodiments of the present invention will be described in detail on the basis of the drawings. In all of the drawings to describe the embodiments, members having the same functions are denoted with the same reference numerals and repeated explanation thereof is omitted. In addition, in the embodiments, explanation of the same portions is not repeated in principle, except for the case in which the explanation is necessary. In addition, in the drawings to describe the embodiments, hatching may be added in a plan view or the hatching may be omitted in a cross-sectional view to easily know a configuration.

### First Embodiment

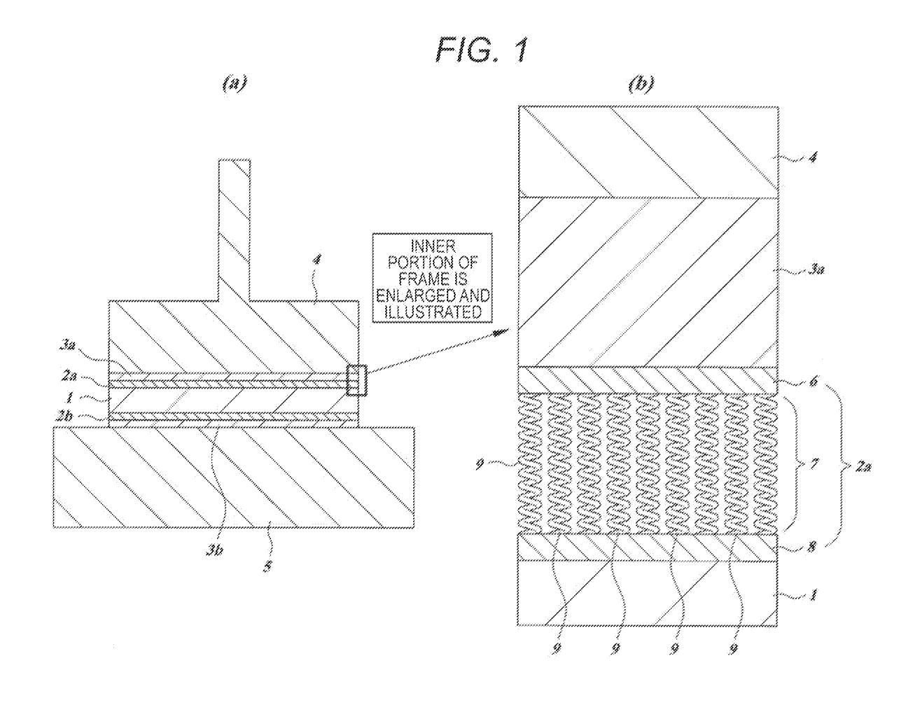

FIG. 1(a) is a cross-sectional view of a semiconductor device to be a first embodiment of the present invention and FIG. 1(b) is an enlarged cross-sectional view illustrating a part of FIG. 1(a).

The semiconductor device according to this embodiment has a packaging structure in which a top surface of a semiconductor chip 1 on which a diode element is formed is electrically connected to a conductive member 4 through a deformation absorption layer 2a and a joining layer 3a and a bottom surface thereof is electrically connected to a conductive member 5 through a deformation absorption layer 2b and a joining layer 3b. The semiconductor device makes a current flowing from one of a pair of conductive members 4 and to the inside rectified by the diode element in the semiconductor chip 1 and the current flow from the other of the conductive members 4 and 5 to the outside and has a function as a diode.

The semiconductor chip 1 is made of single crystal silicon made to have a diode function in a semiconductor manufacturing process (previous process) and has a side of about 6 mm and a thickness of about 0.2 mm as a dimension thereof.

Each of the deformation absorption layers 2a and 2b with the semiconductor chip 1 therebetween includes three kinds of different layers laminated along a thickness direction (vertical direction in the drawings). That is, each of the deformation absorption layers 2a and 2b includes a nano-structure layer 7 arranged at the center of the thickness direction and plate layers 6 and 8 of two layers with the nano-structure layer 7 therebetween, as illustrated in FIG. 1(b).

The nano-structure layer 7 has a structure in which nano-structures 9 having an approximately circular cross-sectional shape with a diameter of about 25 nm and a spring shape with an outer diameter of about 150 nm, an inner diameter of about 100 nm, and a pitch of about 50 nm are two-dimensionally arranged at an interval of about 170 nm. The height of the nano-structure 9 is 10 μm and a main material thereof is copper (Cu).

As such, each of the plurality of nano-structures 9 forming the nano-structure layer 7 has the spring shape having a size of nano-order, that is, 1 μm or less, so that stiffness of the nano-structure layer 7 decreases. Therefore, thermal stress due to a thermal deformation difference of each member forming the semiconductor device can be absorbed by deformation of the nano-structure layer 7.

In addition, the nano-structures 9 using the copper having high thermal conductivity as the main material are two-dimensionally arranged densely, so that thermal resistance of a thickness direction of the nano-structure layer 7 decreases. Thereby, because heat of the semiconductor chip 1 at the time of an operation can be diffused securely to the outside through the deformation absorption layers 2a and 2b, a temperate rise of the semiconductor chip 1 can be suppressed.

Both the joining layer 3a between the deformation absorption layer 2a and the conductive member 4 and the joining layer 3b between the deformation absorption layer 2b and the conductive member 5 are made of a solder material having a thickness of 50 μm. In addition, the conductive members 4 and 5 are made of the copper and have a function as an electrode to flow a current and a function as a radiator plate to emit the heat generated in the semiconductor chip 1 to the outside.

One end of each of the nano-structures 9 of the spring shapes forming the nano-structure layer 7 is fixed to the plate layer 6 and the other end thereof is fixed to the plate layer 8. Each of the plate layers 6 and 8 is made of a flat thin metal film having a thickness of about 5 μm and a main material thereof is nickel (Ni).

The nano-structures 9 are fixed to the plate layers 6 and 8, so that joining places of the nano-structure layer 7 and the joining layers 3a and 3b become flat surfaces. Thereby, joining of the nano-structure layer 7 and the joining layers 3a and 3b is facilitated and the joining layer 3a (or 3b) can be prevented from entering a gap of the nano-structure layer 7 at the time of the joining.

In addition, the plate layers 6 and 8 are configured using the nickel as a main material, so that surface oxidation of the plate layers 6 and 8 in the course of manufacturing the semiconductor device can be prevented. Therefore, defects such as an increase of contact resistance due to a surface oxidation layer can be prevented.

In this embodiment, the nickel is used in the plate layers 6 and 8. However, when generation of the surface oxidation of the plate layers 6 and 8 in the manufacturing course is difficult, such as when a time from generation of the plate layer 8 to provision of the joining layers 3a and 3b is short or when the semiconductor device is manufactured in a vacuum environment, the copper can be used in the plate layers 6 and 8. Because the copper has thermal conductivity higher than thermal conductivity of the nickel, in this case, the thermal resistance can be decreased as compared with the case in which the nickel is used.

As such, it is a big characteristic of the present invention to provide the deformation absorption layers 2a and 2b having the nano-structure layer 7 between the semiconductor chip 1 and the conductive members 4 and 5.

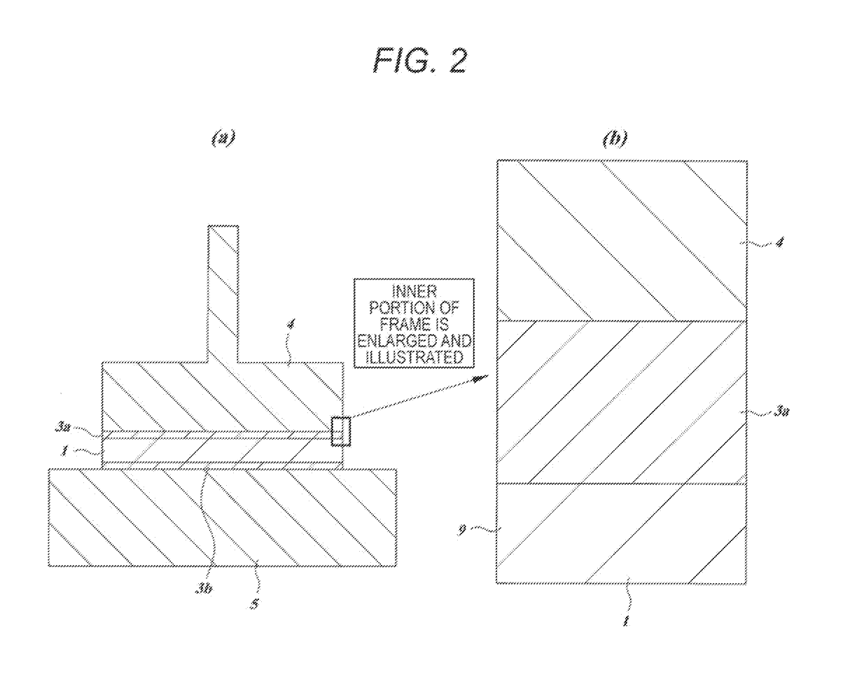

FIG. 2(a) is a cross-sectional view of a semiconductor device to be a comparative example of the present invention and FIG. 2(b) is an enlarged cross-sectional view illustrating a part of FIG. 2(a).

The semiconductor device (comparative example) illustrated in FIGS. 2(a) and 2(b) has a structure in which the deformation absorption layers 2a and 2b are removed from the semiconductor device according to this embodiment illustrated in FIGS. 1(a) and 1(b) and the semiconductor chip 1 and the conductive members 4 and 5 are connected through only the joining layers 3a and 3b.

Because linear expansion coefficients of the conductive members 4 and 5 made of copper and the semiconductor chip 1 made of silicon are greatly different from each other, a thermal deformation difference of the conductive members 4 and 5 and the semiconductor chip 1 is large. For this reason, in the structure illustrated in FIGS. 2(a) and 2(b), the thermal deformation difference of the semiconductor chip 1 and the conductive members 4 and 5 needs to be absorbed by the joining layers 3a and 3b arranged between the semiconductor chip 1 and the conductive members 4 and 5 and it is required that the joining layers 3a and 3b have materials having large thickness and small stiffness. Therefore, in the structure illustrated in FIGS. 2(a) and 2(b), materials capable of being used as the joining layers 3a and 3b may be restricted and the thermal resistance may be increased by an increase in the thickness of the joining layers 3a and 3b.

In addition, when the thermal deformation difference of the semiconductor chip 1 and the conductive members 4 and 5 cannot be absorbed by the joining layers 3a and 3b, like the comparative example, defects such as cracks or malfunctions of the semiconductor chip 1 and destructions of the joining layers 3a and 3b may be generated. For this reason, in the related art, various structures such as forming the joining layers 3a and 3b of a multi-layered structure to improve a deformation absorption function or sealing the entire joining layers with a resin to decrease the thermal deformation difference of the semiconductor chip 1 and the conductive members 4 and 5 are suggested.

Meanwhile, in the semiconductor device according to this embodiment illustrated in FIGS. 1(a) and 1(b), the thermal deformation difference of the semiconductor chip 1 and the conductive members 4 and 5 is absorbed by the deformation absorption layers 2a and 2b including the nano-structure layer 7. Thereby, a packaging structure of high reliability that can prevent the defects such as the cracks or the malfunctions of the semiconductor chip 1 and the destructions of the joining layers 3a and 3b without taking measures such as multilayering of the joining layers 3a and 3b or resin sealing can be provided.

In addition, in the semiconductor device according to this embodiment illustrated in FIGS. 1(a) and 1(b), because the thermal deformation of each member is absorbed by the deformation absorption layers 2a and 2b, it is not necessary to give a deformation absorption function to the joining layers 3a and 3b. Thereby, because the thickness of the joining layers 3a and 3b can be decreased in a range in which the joining is enabled, the thermal resistance can be decreased as compared with the structure of FIGS. 2(a) and 2(b) in which the joining layers 3a and 3b are formed thick to have the deformation absorption function.

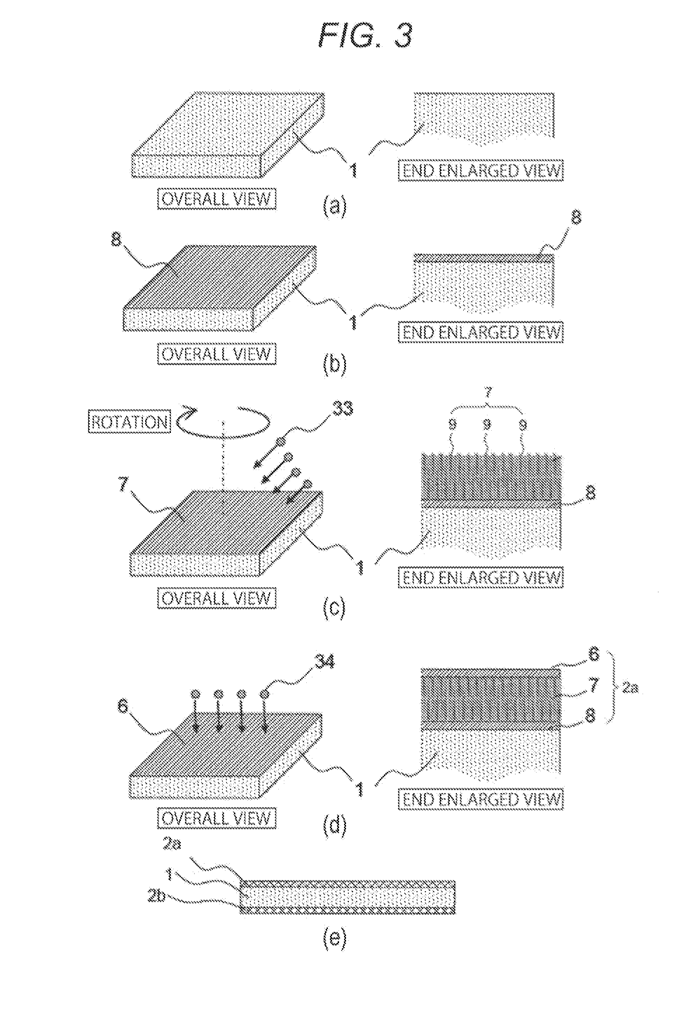

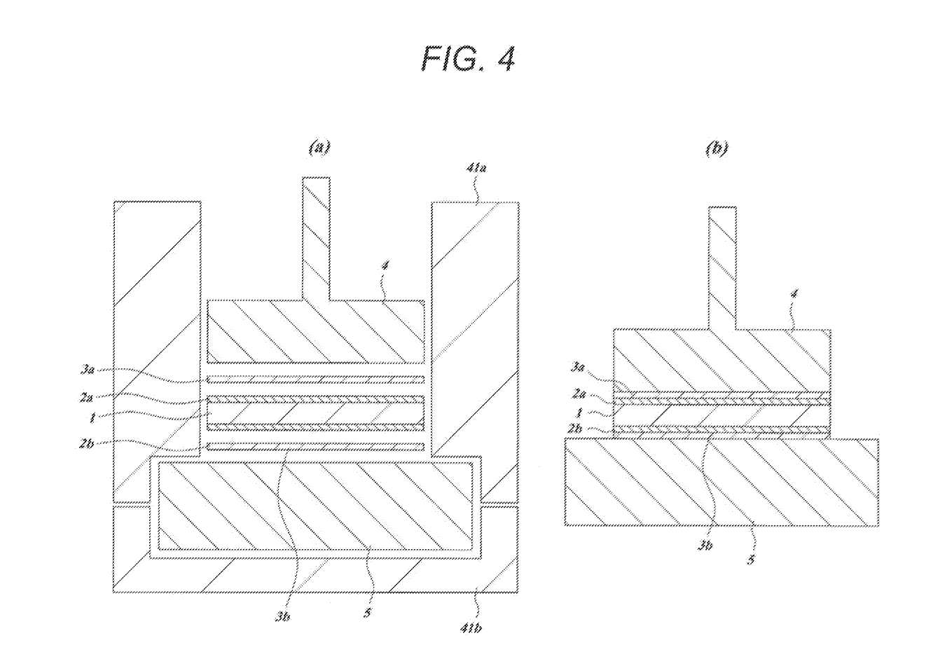

Next, a manufacturing method of the semiconductor device according to this embodiment will be described with reference to FIGS. 3(a) to 4(b).

First, the semiconductor chip 1 illustrated in FIG. 3(a) is prepared. In the semiconductor chip 1, the diode element is formed by the semiconductor manufacturing process (previous process).

Next, as illustrated in FIG. 3(b), the plate layer 8 made of a nickel film is formed on a surface of the semiconductor chip 1 using a evaporation method. The plate layer 8 can be formed using a plating method, instead of the evaporation method. In addition, when a metal layer is formed on a surface of a semiconductor wafer by the semiconductor manufacturing process, the metal layer can be used as the plate layer 8.

Next, as illustrated in FIG. 3(c), while the semiconductor chip 1 is rotated about an axis vertical to the plate layer 8 under an approximately vacuum environment, copper atoms 33 are radiated from a direction oblique to the axis and are deposited. Thereby, the nano-structure layer 7 including the plurality of nano-structures 9 having the spring shapes of the nano-order is formed on the surface of the plate layer 8.

Next, after the rotation of the semiconductor chip 1 is stopped, as illustrated in FIG. 3(d), nickel atoms 34 are deposited from the upper side of the nano-structure layer 7, so that the plate layer 6 is formed on an upper portion of the nano-structure layer 7. By the previous process, the deformation absorption layer 2a including the plate layer 8, the nano-structure layer 7, and the plate layer 6 is formed on the surface of the semiconductor chip 1.

Next, the same sequence is executed after the surface and the back surface of the semiconductor chip 1 are reversed, so that the deformation absorption layer 2b including the plate layer 8, the nano-structure layer 7, and the plate layer 6 is formed on the back surface of the semiconductor chip 1 (FIG. 3(e).

In the manufacturing method described above, after the semiconductor chip 1 is prepared by dicing the semiconductor wafer, the deformation absorption layers 2a and 2b are formed on both surfaces of the semiconductor chip 1. However, after the deformation absorption layers 2a and 2b are formed on both surfaces of the semiconductor wafer according to the above sequence, the semiconductor chip 1 may be separated by dicing the semiconductor wafer. In this case, the deformation absorption layers 2a and 2b can be formed collectively in the plurality of semiconductor chips 1 obtained from the semiconductor wafer. However, because it is necessary to give attention not to damage the deformation absorption layers 2a and 2b at the time of dicing the semiconductor wafer, it is desirable to select an appropriate method according to a dicing method.

Next, as illustrated in FIG. 4(a), after the joining layer 3b, the semiconductor chip 1 on which the deformation absorption layers 2a and 2b are formed, the joining layer 3a, and the conductive member 4 are sequentially overlapped on the upper portion of the conductive member 5, a laminated object is exposed under an environment in which a temperature is equal to or more than a melting temperature of the solder material forming the joining layers 3a and 3b.

Thereby, the deformation absorption layer 2a and the conductive member 4 of the surface of the semiconductor chip 1 are joined through the joining layer 3a and the deformation absorption layer 2b and the conductive member 5 of the back surface of the semiconductor chip 1 are joined through the joining layer 3b.

At this time, in this embodiment, the laminated object is fixed by joining jigs 41a and 41b made of carbon to prevent a position deviation between the individual members forming the laminated object. In addition, at the time of the joining, the laminated object fixed by the joining jigs 41a and 41b is accommodated in a reflow furnace and is heated in an approximately vacuum environment, so that non-joining portions or voids generated in the joining layers 3a and 3b are decreased.

Then, an inner portion of the reflow furnace is cooled down and the laminated object is extracted from the joining jigs 41a and 41b, so that the semiconductor device according to this embodiment is finished (FIG. 4(b)).

According to the manufacturing method described above, the nano-structure layer 7 in which the plurality of nano-structures 9 having the spring shapes of the dimension of nano-order, that is, less than 1 μm are arranged densely can be manufactured. Therefore, a semiconductor packaging structure that is remarkably different from that in the related art can be realized.

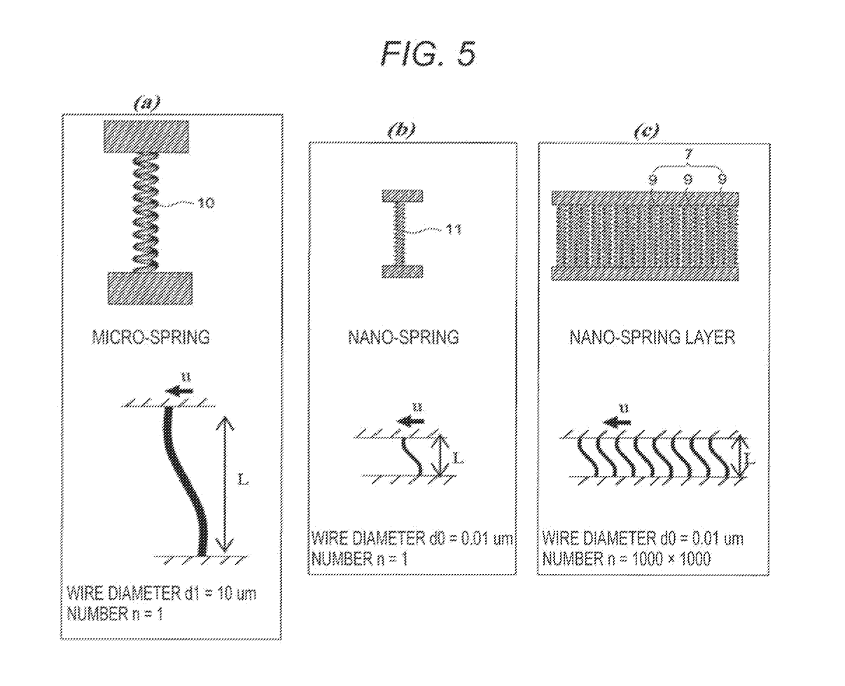

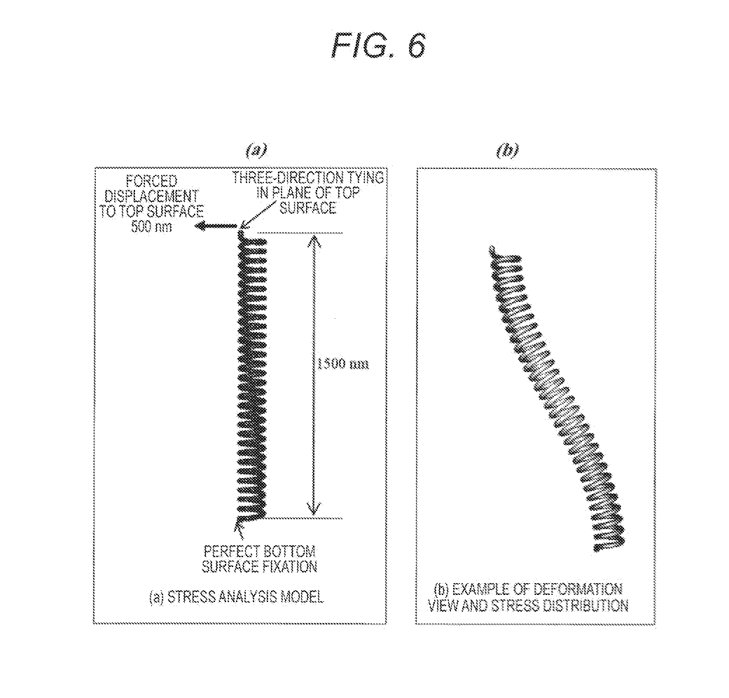

Next, characteristics of the semiconductor packaging structure according to the present invention will be described. FIG. 5(a) illustrates a spring 10 having a dimension of micro-order in the related art, FIG. 5(b) illustrates a spring 11 of nano-order obtained by simply scaling down the spring illustrated in FIG. 5(a), and FIG. 5(c) illustrates the nano-structure layer 7 according to this embodiment in which the nano-structures 9 having the spring shapes of the nano-order are arranged densely.

Because the deformation absorbed by the deformation absorption layers is mainly shear deformation, each of the springs is regarded as one needle to which the shear deformation is applied and the spring 10 of the micro-order, the spring 11 of the nano-order, and the nano-structure layer 7 are modeled as one needle having a wire diameter of 10 μm, one needle having a wire diameter of 10 nm, and 1000000 (=1000×1000) needles having a wire diameter of 10 nm, respectively. The height of all the needles (the thickness of the nano-structure layer 7) is set as the same value L.

At this time, maximum stress (σᵣₙₐₓ) generated in the needles is represented by the following expression:

$${σ}_{max} = \frac{3}{4} \frac{Edu}{{L}^{2}} \qquad [ Mathematical Formula 1 ]$$

(in the expression, E shows longitudinal elasticity modulus, d shows a wire diameter, and u shows applied shear displacement).

From the expression, the stress generated in the nano-structure layer 7 and the spring 11 of the nano-order is the same. However, stress of 1000 times is generated in the spring 10 of the micro-order in which d is 1000 times and destruction prevention thereof becomes a problem.

Meanwhile, thermal resistance (R) is represented by the following expression:

$$R = \frac{4 L}{λ π {d}^{2} n} \qquad [ Mathematical Formula 2 ]$$

(in the expression, λ shows thermal conductivity of a material and n shows a number).

From the expression, the thermal resistance of the nano-structure layer 7 and the spring 10 of the micro-order is the same. However, because the thermal resistance becomes 1000000 times in the spring 11 of the nano-order, a temperature rise of the semiconductor chip becomes remarkable. In order to make the stress generated in the spring 10 of the micro-order equal to the stress generated in the nano-structure layer 7, the height L needs to be set to 32 times. In this case, the thermal resistance becomes 32 times.

From this, it can be known that a function of realizing both the deformation absorption and the low thermal resistance required in the semiconductor packaging structure is a function that cannot be realized in the spring 10 of the micro-order according to the related art and the spring 11 of the nano-order obtained by simply scaling down the spring and can be realized first by the present invention.

FIG. 6(a) illustrates a stress analyzing model of the nano-structure 9 according to this embodiment. The actual height of the nano-structure 9 is 10 μm, but the height of 1500 nm is modeled herein. In addition, FIG. 6(b) illustrates an example of a deformation view and a stress distribution of the nano-structure 9 obtained by executing the stress analysis.

A dark place of FIG. 6(b) is a place where stress is large. It can be known that the shear deformation is absorbed by the deformation of the entire spring and stress of both upper and lower ends is large as compared with a center portion.

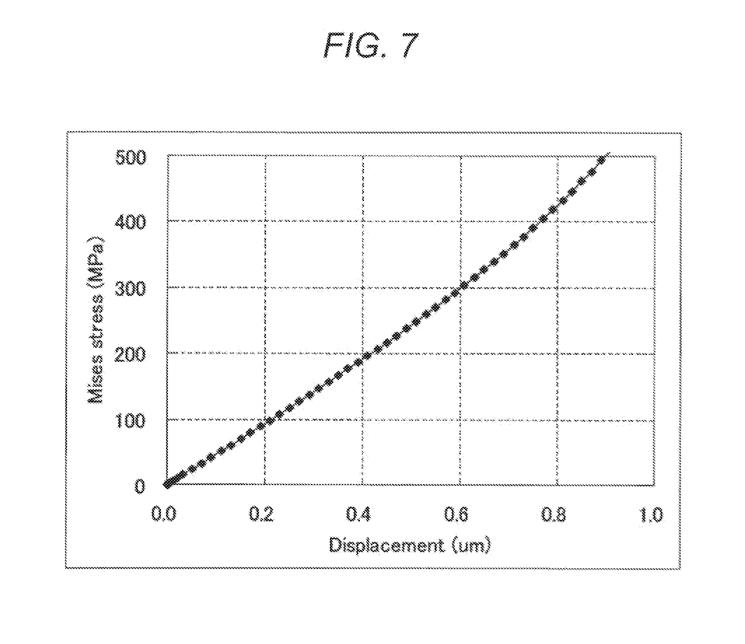

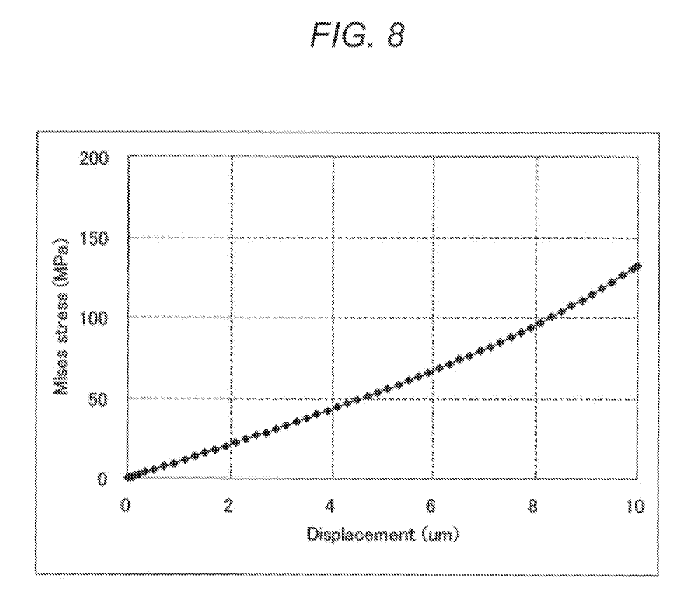

FIG. 7 is a graph illustrating a relation of a shear displacement amount (unit: μm) and maximum stress (unit: MPa) obtained from the stress analysis. In addition, FIG. 8 is a graph illustrating a relation of a shear displacement amount (unit: μm) and maximum stress (unit: MPa) in the nano-structure 9 having the height of 10 μm, acquired from a result of FIG. 7.

In the semiconductor device according to this embodiment, the shear displacement amount is largest in the vicinity of the end of the semiconductor chip 1. The shear displacement amount at the corresponding position is 8.4 μm when a distance from the center of the semiconductor chip 1 is 3 mm, a linear expansion coefficient of the semiconductor chip 1 is 3 ppm/° C., a linear expansion coefficient of the conductive member is 17 ppm/° C., and a temperature change is 200° C.

From FIG. 8, it can be confirmed that, in the case of the nano-structure 9 having the height of 10 μm, the maximum stress generated in the shear displacement amount of 8.4 μm is about 100 MPa and is fatigue life satisfying the number of times required in the semiconductor device from fatigue strength of a copper material. The fatigue strength of the copper herein is described in “The society of materials science, Databook on fatigue strength of metallic materials, (1996), Elsevier Science”.

Next, the thermal conductivity is confirmed. The thermal conductivity of the nano-structure layer 7 in a thickness direction becomes smaller than the thermal conductivity of copper of a bulk material, due to a space formed in the nano-structure layer 7 (small volume occupancy of the copper) and a long thermal conduction path for a spiral shape of the nano-structure 9.

Occupancy of the nano-structure 9 according to this embodiment in the volume of the nano-structure layer 7 is about 13%. If it is assumed that the thermal conductivity is decreased by one digit due to an increase in the conductivity path, the thermal conductivity of the nano-structure layer 7 in the thickness direction becomes about 1/100 of the thermal conductivity of the copper. This thermal conductivity is thermal conductivity of about 1/10 of the solder material used as the joining layers 3a and 3b. Therefore, the thermal resistance of the nano-structure layer 7 having the thickness of 10 μm is equal to the thermal resistance of the solder layer having the thickness of 100 μm and the thermal resistance of the nano-structure layer 7 does not become a remarkable problem. As illustrated by the comparison of FIGS. 1(a) and 1(b) and FIGS. 2(a) and 2(b), in the semiconductor packaging structure according to this embodiment, the thickness of the joining layers 3a and 3b can be decreased. Therefore, if the thickness of the joining layers 3a and 3b can be decreased by 100 μm or more, the entire thermal resistance can be decreased.

As described above, it has been confirmed that the semiconductor device according to this embodiment has the sufficient fatigue strength and the low thermal resistance.

### Second Embodiment

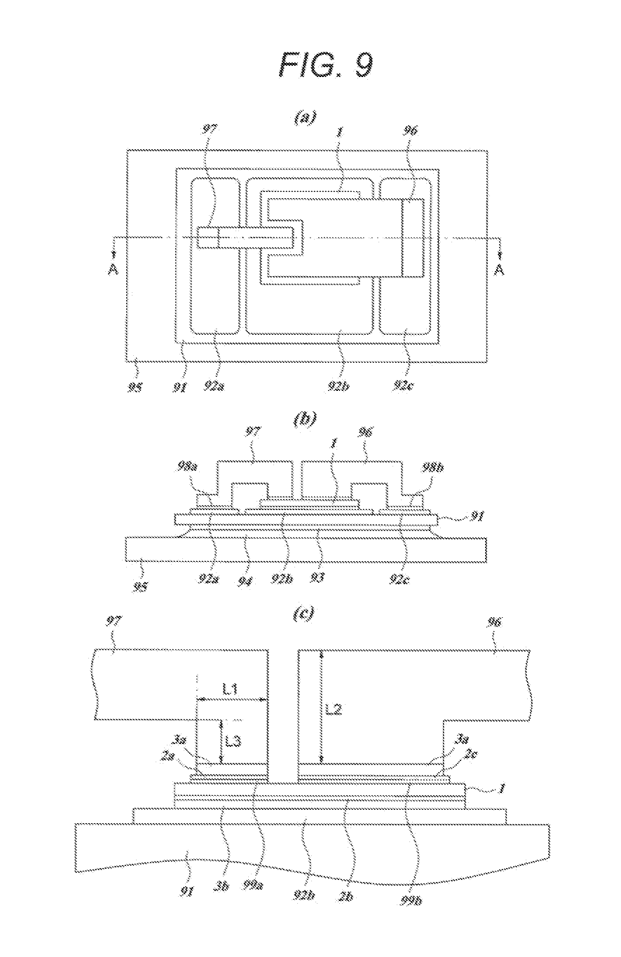

FIG. 9(a) is a plan view of a semiconductor device to be a second embodiment of the present invention, FIG. 9(b) is a cross-sectional view taken along the line A-A of FIG. 9(a), and FIG. 9(c) is an enlarged cross-sectional view illustrating a part of FIG. 9(b).

The semiconductor device according to this embodiment has a structure in which a semiconductor chip 1 on which an insulated gate bipolar transistor (IGBT) is formed is packaged on a ceramic substrate 91. A plurality of circuit patterns 92a, 92b, and 92c are formed on a top surface of the ceramic substrate 91 and a metal pattern 93 is formed on a bottom surface thereof. The ceramic substrate 91 is joined to a top surface of a base member 95 through a joining material 94 arranged on a bottom surface of the metal pattern 93.

As illustrated in FIG. 9(c), a deformation absorption layer 2b is formed on a bottom surface of the semiconductor chip 1. The semiconductor chip 1 is electrically connected to the circuit pattern 92a through a joining layer 3b arranged on a bottom surface of the deformation absorption layer 2b. Meanwhile, a gate terminal 99a and an emitter terminal 99b of the IGBT are formed on a top surface of the semiconductor chip 1. In addition, the deformation absorption layer 2a is formed on an upper portion of the gate terminal 99a and the deformation absorption layer 2c is formed on an upper portion of the emitter terminal 99b. In addition, the gate terminal 99a is electrically connected to one end of a gate terminal joining member 97 through the joining layer 3a arranged on an upper portion thereof and the emitter terminal 99b is electrically connected to one end of an emitter terminal joining member 96 through the joining layer 3b arranged on an upper portion thereof. In addition, as illustrated in FIG. 9(b), the other end of the gate terminal joining member 97 is electrically connected to the circuit pattern 92a through a joining material 98a and the other end of the emitter terminal joining member 96 is electrically connected to the circuit pattern 92c through a joining member 98b.

Although not illustrated in FIGS. 9(a) to 9(c), each of the deformation absorption layers 2a, 2b, and 2c is configured to have the same structure as the deformation absorption layers 2a and 2b according to the above-described embodiment. That is, each of the deformation absorption layers 2a, 2b, and 2c includes a nano-structure layer 7 and plate layers 6 and 8 of two layers with the nano-structure layer 7 therebetween and the nano-structure layer 7 has a structure in which a plurality of nano-structures 9 having spiral shapes are arranged densely. In addition, copper having high thermal conductivity is used in the circuit patterns 92a, 92b, and 92c, the emitter terminal joining member 96, and the gate terminal joining member 97, so that thermal resistance between the semiconductor chip 1 and the outside decreases.

An actual semiconductor device includes a terminal to take electrical connection of the circuit patterns 92a, 92b, and 92c and the outside, a case or a cover to protect the semiconductor device, and sealing gel to seal the semiconductor device, in addition to the members illustrated in FIGS. 9(a) to 9(c). However, because these members do not affect the functions of the present invention, illustration and description thereof are omitted.

A large difference between the first embodiment and the second embodiment is that the plurality of terminals (the gate terminal 99a and the emitter terminal 99b) are provided on the top surface of the semiconductor chip 1 to make the semiconductor chip 1 have a function as the IGBT. For this reason, different from the first embodiment, the plurality of deformation absorption layers 2a and 2c are arranged on the top surface of the semiconductor chip 1. In addition, the terminal joining members (the gate terminal joining member 97 and the emitter terminal joining member 96) having almost the same bottom surface dimension as a plane dimension of the terminals (the gate terminal 99a and the emitter terminal 99b) are connected to the upper portions of the deformation absorption layers 2a and 2c, so that heat generated from the semiconductor chip 1 at the time of an operation can be effectively emitted from not only the bottom surface side of the semiconductor chip 1 but also the top surface side thereof.

The terminal joining members (the gate terminal joining member 97 and the emitter terminal joining member 96) have large length and large stiffness. For this reason, when the deformation absorption layers 2a and 2c are not provided, reliability deterioration of the joining layer 3a due to a thermal deformation difference of the semiconductor chip 1 and the terminal joining members (the gate terminal joining member 97 and the emitter terminal joining member 96) becomes a problem. Therefore, in this case, members having a small size and small stiffness like wire are generally used in electrical connection of the terminals (the gate terminal 99a and the emitter terminal 99b) and the circuit patterns 92a, 92b, and 92c.

However, according to this embodiment, because the thermal deformation difference of the semiconductor chip 1 and the terminal joining members (the gate terminal joining member 97 and the emitter terminal joining member 96) is absorbed by the deformation absorption layers 2b and 2c, high reliability can be secured and the thermal resistance between the semiconductor chip 1 and the terminal joining members (the gate terminal joining member 97 and the emitter terminal joining member 96) can be decreased.

If a place having a small cross-sectional area exists in a part of the terminal joining members (the gate terminal joining member 97 and the emitter terminal joining member 96), a position thereof becomes a narrow path of a heat radiation path. Therefore, in this embodiment, the shapes of the terminal joining members (the gate terminal joining member 97 and the emitter terminal joining member 96) are determined to become bigger than the shape of the terminal (in this case, the gate terminal 99a) having a small area. In addition, in this embodiment, as illustrated in FIG. 9(c), a constant gap L3 is provided between an outer circumferential portion of the semiconductor chip 1 and the terminal joining members (the gate terminal joining member 97 and the emitter terminal joining member 96), so as to prevent a contact of the outer circumferential portion of the semiconductor chip 1 and the terminal joining members (the gate terminal joining member 97 and the emitter terminal joining member 96).

From this, the height L2 of the terminal joining members (the gate terminal joining member 97 and the emitter terminal joining member 96) in the upper portion of the semiconductor chip 1 becomes larger than a connection width L1 of the gate terminal joining member 97 and the gate terminal 99a.

### Third Embodiment

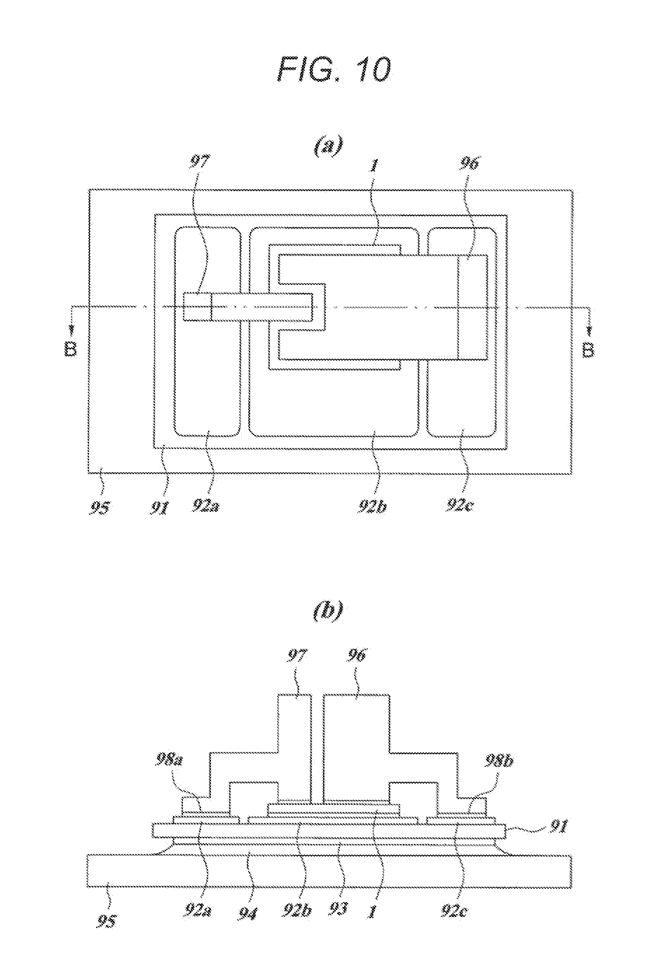

FIG. 10(a) is a plan view of a semiconductor device to be a third embodiment of the present invention and FIG. 10(b) is a cross-sectional view taken along the line B-B of FIG. 10(a).

Similar to the semiconductor device according to the second embodiment, the semiconductor device according to this embodiment has a structure in which a semiconductor chip 1 on which an IGBT is formed is packaged on a ceramic substrate 91. However, this embodiment is different from the second embodiment in that heights of terminal joining members (a gate terminal joining member 97 and an emitter terminal joining member 96) in an upper portion of the semiconductor chip 1 become larger than heights of the other places.

In this case, because volumes of the terminal joining members (the gate terminal joining member 97 and the emitter terminal joining member 96) in the vicinity of the semiconductor chip 1 increase, heat capacities of the terminal joining members in the vicinity of the semiconductor chip 1 increase. Therefore, a temperature change of the semiconductor chip 1 when the semiconductor chip 1 repeats an operation and a stop can be decreased, a stabilized operation can be secured, and thermal fatigue life can be further improved.

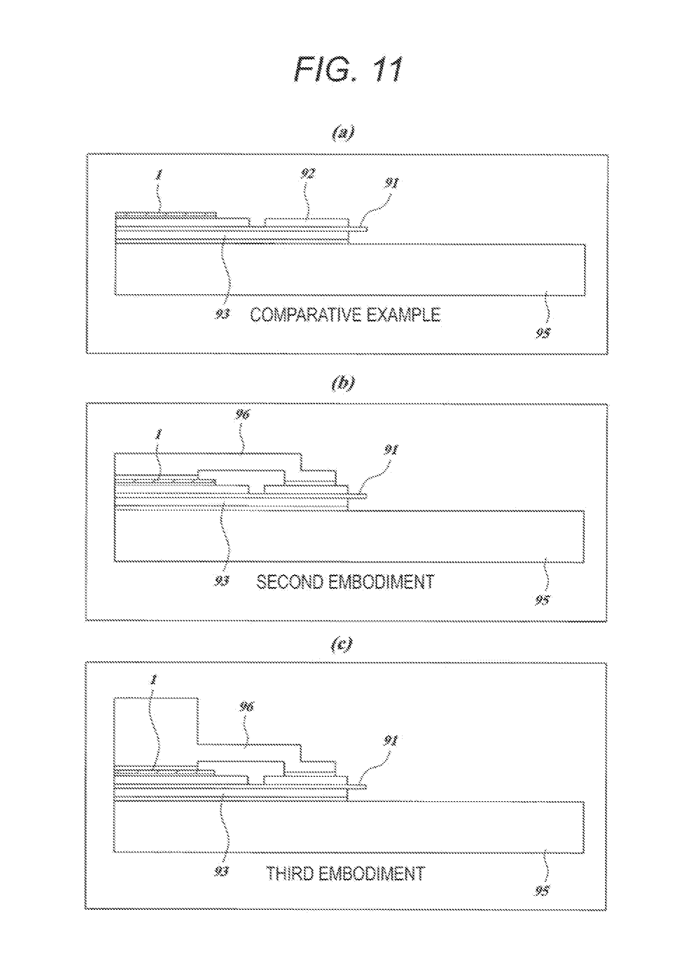

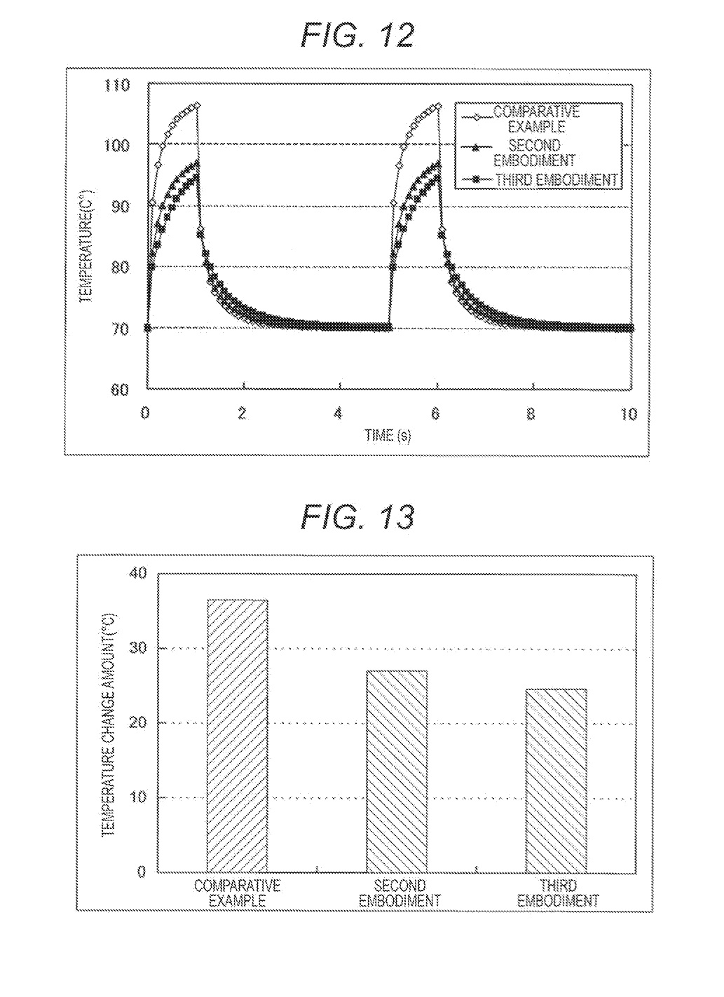

Next, effects of the second and third embodiments will be described using FIGS. 11(a) to 12. FIG. 11(a) is a partial cross-sectional view illustrating a structure according to a comparative example in which deformation absorption layers 2b and 2c and the terminal joining members (the gate terminal joining member 97 and the emitter terminal joining member 96) are not provided and FIG. 11(b) is a partial cross-sectional view illustrating a structure according to the second embodiment, and FIG. 11(c) is a partial cross-sectional view illustrating a structure according to a third embodiment.

In these structures, the temperature change of the semiconductor chip 1 when the semiconductor chip 1 repeats the heat generation and the stop is calculated by a thermal conduction analysis. In addition, conditions in which cooling water of 70° C. is flown to a bottom surface of a base member 95 and heat of the semiconductor chip 1 is emitted from the side of the bottom surface of the base member 95 are set. A calculation result is illustrated in FIG. 12.

In all the structures, an amount of heat generated from the semiconductor chip 1 at the time of heat generation is the same. However, a temperature of the semiconductor chip 1 is significantly different according to the structure. That is, the temperature of the semiconductor chip 1 when the heat generation ends is high in order of the structure according to the comparative example, the structure according to the second embodiment, and the structure according to the third embodiment.

FIG. 13 illustrates a temperature change amount of each structure. A temperature change amount of the structure according to the comparative example is 36° C., but temperature change amounts of the structures according to the second and third embodiments are 27° C. and 24° C., respectively, and are decreased to 75% and 67%, respectively, for the structure according to the comparative example. As such, it can be confirmed that the temperature change of the semiconductor chip 1 can be decreased by using the structure according to the second embodiment or the third embodiment.

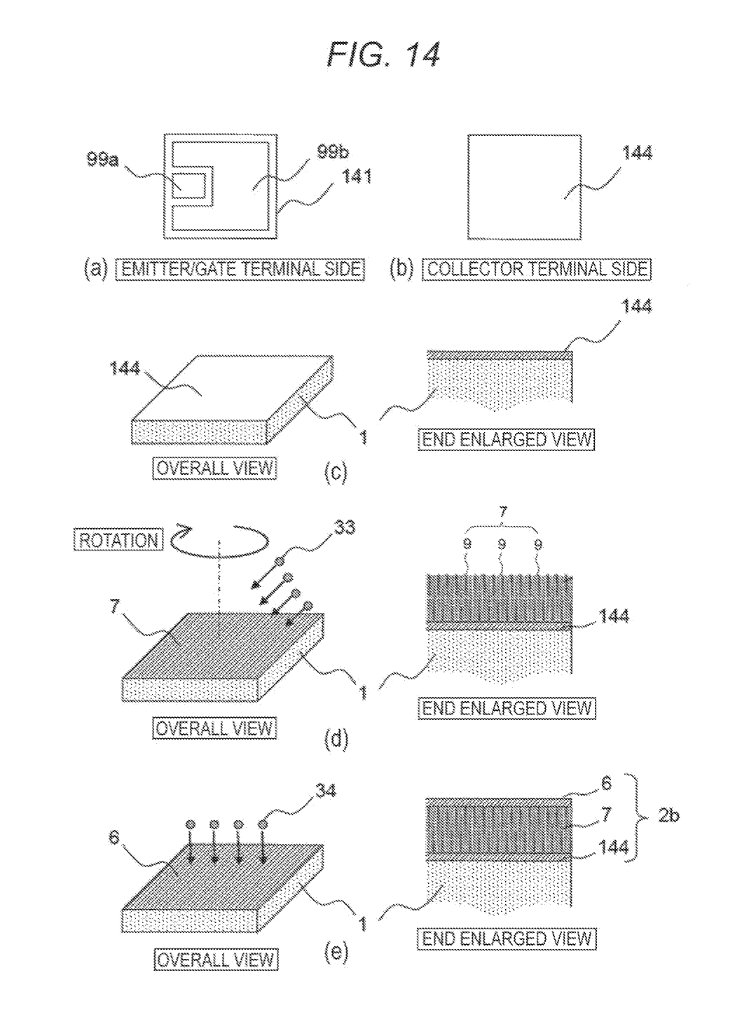

Next, manufacturing methods of the semiconductor devices according to the second and third embodiments will be described using FIGS. 14(a) to 16(b).

First, the semiconductor chip 1 illustrated in FIGS. 14(a), 14(b), and 14(c) is prepared. As illustrated in FIG. 14(a), the gate terminal 99a connected to a gate of the IGBT and the emitter terminal 99b connected to an emitter of the IGBT are formed on the top surface of the semiconductor chip 1. As illustrated in FIGS. 14(b) and 14(c), a collector terminal 144 connected to a collector of the IGBT is formed on the bottom surface of the semiconductor chip 1. The gate terminal 99a and the emitter terminal 99b are formed on the top surface of the semiconductor wafer by a semiconductor manufacturing process (previous process) and the collector terminal 144 is formed on the bottom surface of the semiconductor wafer by the semiconductor manufacturing process.

Next, as illustrated in FIG. 14(d), the nano-structure layer 7 including the plurality of nano-structures 9 having the spring shapes of the nano-order is formed on a surface of the collector terminal 144 of the semiconductor chip 1. A method of forming the nano-structure layer 7 is the same as the method according to the first embodiment described in FIG. 3(c). While the semiconductor chip 1 is rotated about an axis vertical to the collector terminal 144 under an approximately vacuum environment, copper atoms 33 are deposited from a direction oblique to the axis.

Next, after the rotation of the semiconductor chip 1 is stopped, as illustrated in FIG. 14(e), nickel atoms 34 are deposited from the upper side of the nano-structure layer 7, so that the plate layer 6 is formed on an upper portion of the nano-structure layer 7. By the previous process, the deformation absorption layer 2b including the collector terminal 144, the nano-structure layer 7, and the plate layer 6 is formed on the surface of the semiconductor chip 1.

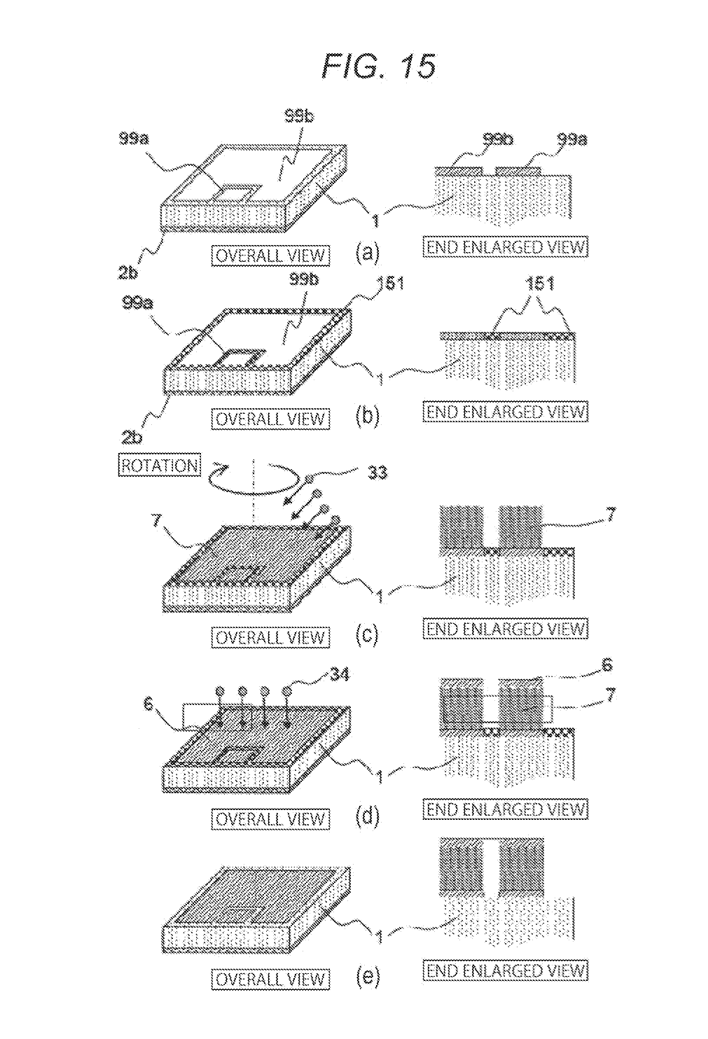

Next, as illustrated in FIG. 15(a), the surface and the back surface of the semiconductor chip 1 are reversed to make the surface on which the gate terminal 99a and the emitter terminal 99b are formed become the upper side. Then, as illustrated in FIG. 15(b), a mask 151 made of an insulating material is formed in a region other than the surface of the gate terminal 99a and the surface of the emitter terminal 99b in the top surface of the semiconductor chip 1.

At this time, it is desirable to make the thickness of the mask 151 equal to the thickness of the gate terminal 99a and the emitter terminal 99b. This is because, in the case in which the thickness of the mask 151 and the thickness of the gate terminal 99a and the emitter terminal 99b are different from each other, when the atoms constituting the nano-structure are deposited from an oblique direction in a next process, position precision of the deposited atoms is deteriorated.

Next, as illustrated in FIG. 15(c), while the semiconductor chip 1 is rotated about an axis vertical to the plate layer 8 under an approximately vacuum environment, the copper atoms 33 are deposited from a direction oblique to the axis. Thereby, the nano-structure layer 7 including the plurality of nano-structures 9 having the spring shapes of the nano-order is formed on the surface of the gate terminal 99a and the surface of the emitter terminal 99b. At this time, the nano-structure 9 is not formed on the surface of the mask 151 made of the insulating material.

Next, after the rotation of the semiconductor chip 1 is stopped, as illustrated in FIG. 15(d), the nickel atoms 34 are deposited from the upper side of the nano-structure layer 7, so that the plate layer 6 is formed on an upper portion of the nano-structure layer 7. At this time, the plate layer 6 is not formed on the surface of the mask 151 not having the nano-structure 9.

Next, as illustrated in FIG. 15(e), the mask 151 of the top surface of the semiconductor chip 1 is removed, so that the deformation absorption layer 2a including the gate terminal 99a, the nano-structure layer 7, and the plate layer 6 and the deformation absorption layer 2c including the emitter terminal 99b, the nano-structure layer 7, and the plate layer 6 are formed.

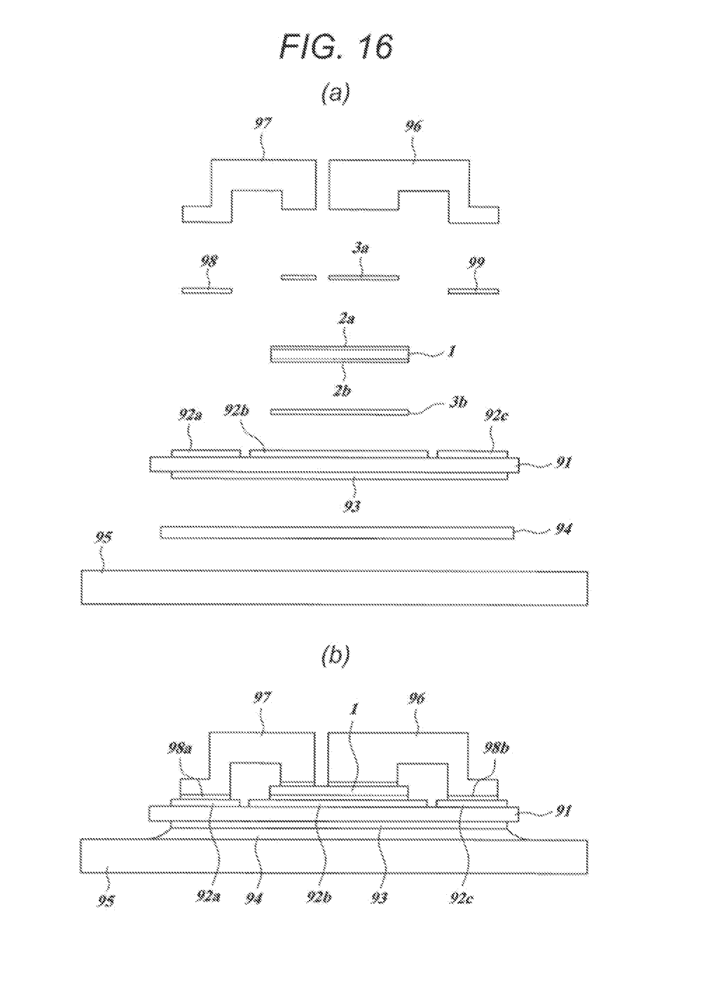

Next, as illustrated in FIG. 16(a), each member is laminated and a temperature is increased to a temperature equal to or more than a melting point of the joining layer 3. Thereby, as illustrated in FIG. 16(b), the semiconductor device according to the second embodiment or the third embodiment is finished. At this time, it is desirable to fix each member using joining jigs (not illustrated in the drawings) to prevent the position deviation of each member before the joining, similar to the manufacturing method according to the first embodiment.

### Fourth Embodiment

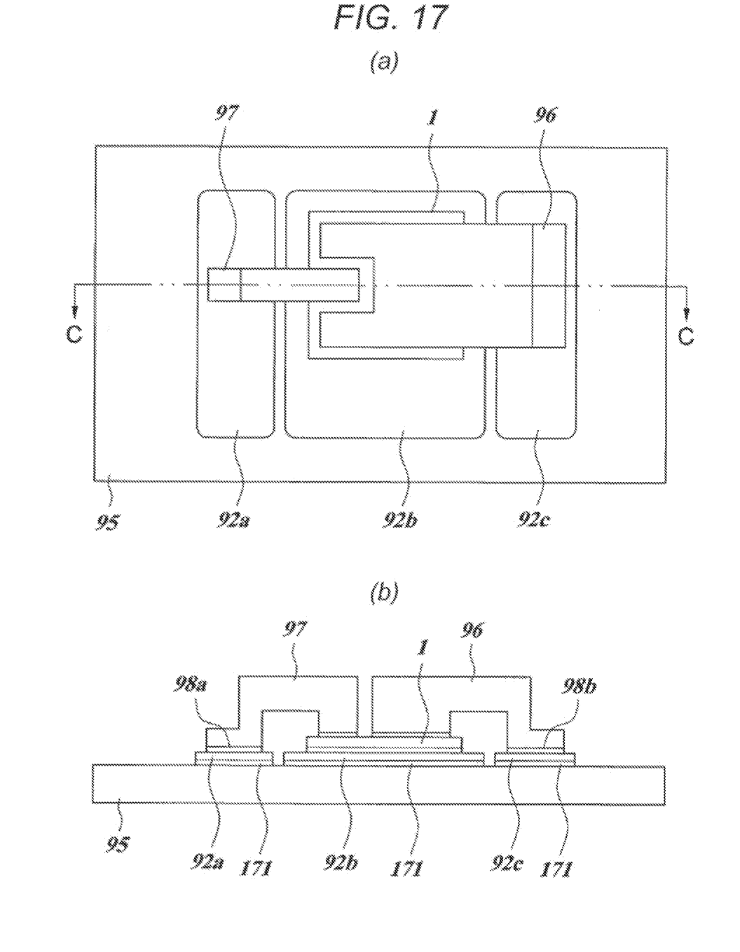

FIG. 17(a) is a plan view of a semiconductor device to be a fourth embodiment of the present invention and FIG. 17(b) is a cross-sectional view taken along the line C-C of FIG. 17(a).

Similar to the semiconductor devices according to the second and third embodiments, the semiconductor device according to this embodiment uses a semiconductor chip 1 on which an IGBT is formed. A difference of the fourth embodiment and the second and third embodiments is that circuit patterns 92a, 92b, and 92c and a base member 95 are connected through a nano-structure layer 171 in which a plurality of nano-structures made of an insulating material such as ceramic are two-dimensionally arranged.

According to a packaging structure according to this embodiment, insulation of the base member 95 and the circuit patterns 92a, 92b, and 92c can be secured without using the ceramic substrate 91, the metal pattern 93, and the joining material 94 used in the second and third embodiments.

In addition, because a thermal deformation difference of the base member 95 and the circuit patterns 92a, 92b, and 92c is absorbed by the nano-structure layer 171 made of the ceramic material, a semiconductor device having high reliability can be provided.

### Fifth Embodiment

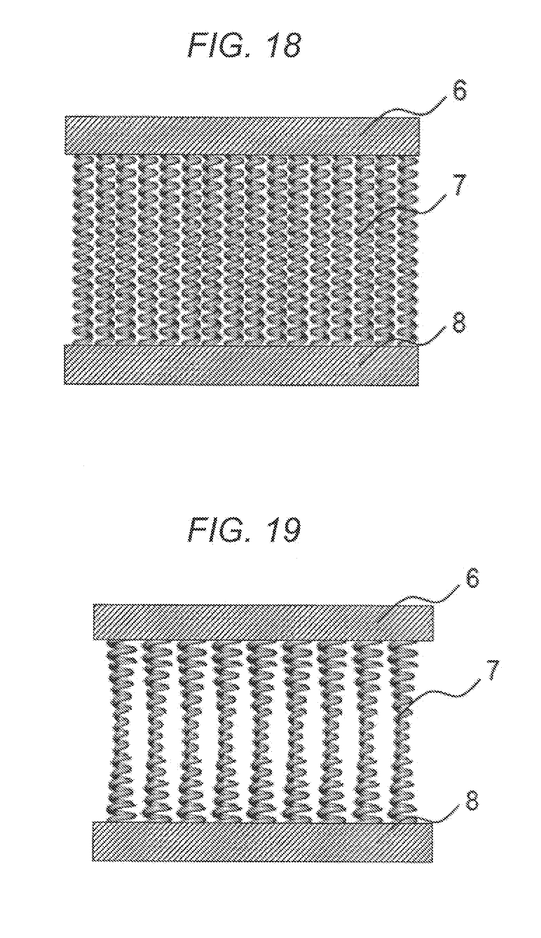

As illustrated in FIG. 18, the nano-structure layer 7 used in the first embodiment has the structure in which the nano-structures 9 having the spring shapes are two-dimensionally arranged and a diameter of each nano-structure 9 is the same in an upper end, a center portion, and a lower end.

Meanwhile, the diameter of the center portion of the nano-structure 9 used in this embodiment is smaller than the diameters of both the upper and lower ends, as illustrated in FIG. 19. The nano-structure 9 having the above shape can be manufactured by changing a rotation number of the semiconductor chip 1 in the middle of the rotation, in the manufacturing process of the nano-structure layer 7 according to the first embodiment illustrated in FIG. 3(c).

As described using FIGS. 6(a) and 6(b), if forced displacement of a shear direction is applied to the nano-structure 9 having the spring shape, large stress is generated in both the upper and lower ends of the nano-structure rather than the center portion. Therefore, the nano-structure 9 according to this embodiment illustrated in FIG. 19 is used, so that stiffness of the spring decreases in the center portion of the nano-structure 9 having the small diameter and displacement absorbed at the corresponding position increases. As a result, maximum stress generated in both the upper and lower ends of the nano-structure 9 can be decreased.

The nano-structure 9 according to this embodiment is used in combination with the first to fourth embodiments, so that a semiconductor device having improved reliability can be provided.

### Sixth Embodiment

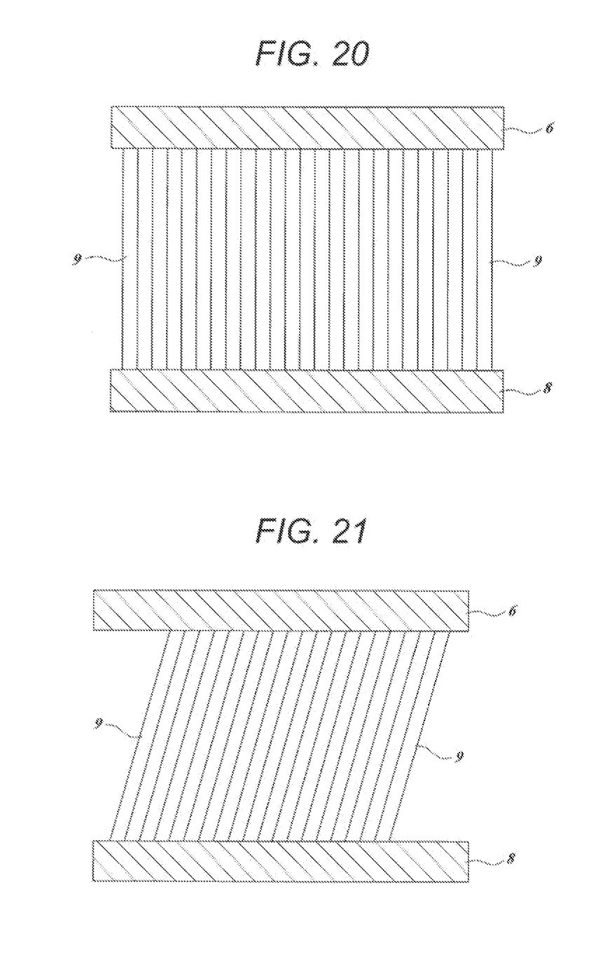

The nano-structure layer 7 used in the first to fifth embodiments has the structure in which the nano-structures 9 having the spring shapes are two-dimensionally arranged. Meanwhile, a nano-structure layer 7 according to this embodiment has a structure in which nano-structures 9 having columnar shapes are two-dimensionally arranged, as illustrated in FIG. 20. The nano-structure 9 having the above shape can be manufactured by increasing the rotation speed of the semiconductor chip 1 and coupling springs along a vertical direction, in the manufacturing process of the nano-structure layer 7 according to the first embodiment illustrated in FIG. 3(c).

In the nano-structure 9 according to this embodiment, a deformation absorption function is inferior as compared with the nano-structures 9 according to the first to fifth embodiments having the spring shapes. However, because the heat capacity is large as compared with the nano-structures 9 having the spring shapes, thermal conductivity of a height direction is improved.

In addition, because volume occupancy of the nano-structure 9 can be increased as compared with the nano-structure layers 7 according to the first to fifth embodiments, thermal resistance or electrical resistance of the nano-structure layer 7 can be further decreased. Therefore, the nano-structure 9 according to this embodiment can be used effectively for a product in which thermal resistance reduction is further required.

### Seventh Embodiment

As illustrated in FIG. 21, a nano-structure layer 7 according to this embodiment is characterized in that each of nano-structures 9 has an inclination for facing surfaces with a plate layer 6 and a plate layer 8. The nano-structure layer 7 having the nano-structures 9 of the above shape can be manufactured by a next method.

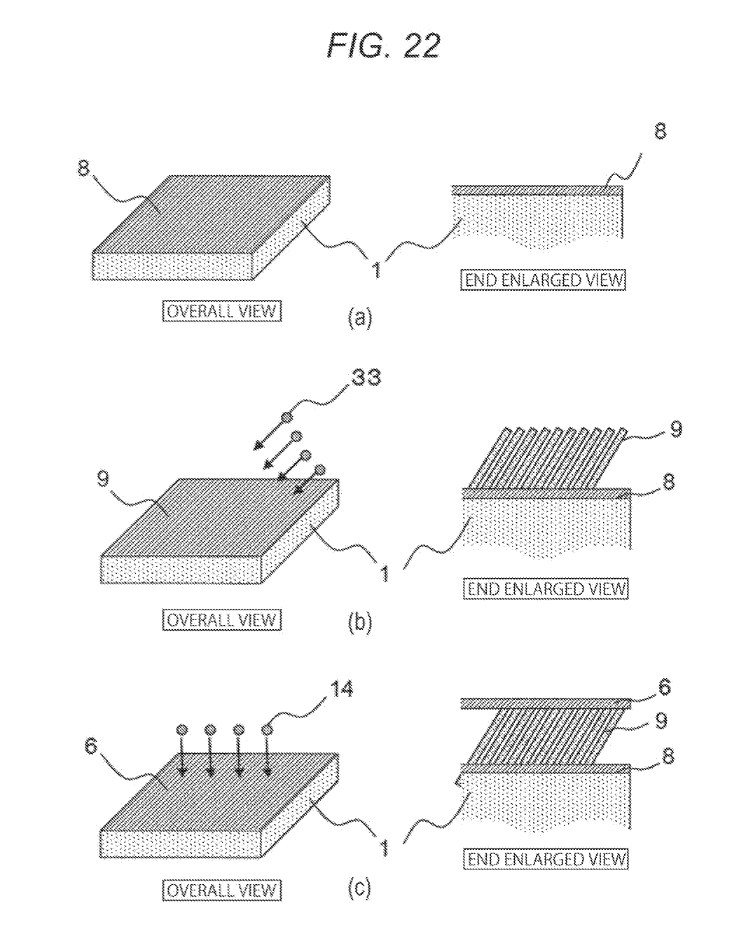

First, as illustrated in FIG. 22(a), a semiconductor chip 1 of which a top surface is provided with the plate layer 8 is prepared. Next, as illustrated in FIG. 22(b), copper atoms 33 are deposited from a direction oblique to a top surface of the plate layer 8, under an approximately vacuum environment. A manufacturing method according to this embodiment is different from the manufacturing methods according to the other embodiments in that the atoms 33 are deposited without rotating the semiconductor chip 1 at that time. Therefore, in this embodiment, a deposition device does not need to have a function of rotating the semiconductor chip 1.

Then, as illustrated in FIG. 22(c), nickel atoms 34 are deposited from the upper side of the nano-structure layer 7, so that the plate layer 6 is formed on an upper portion of the nano-structure layer 7.

In the nano-structure layer 7 according to this embodiment manufactured by the above method, because the nano-structures 9 are not formed in a part of a top surface of the plate layer 8 or a part of a bottom surface of the plate layer 6, electrical conductivity or thermal conductivity of the nano-structure layer 7 is slightly decreased as compared with the other embodiments.

### Eighth Embodiment

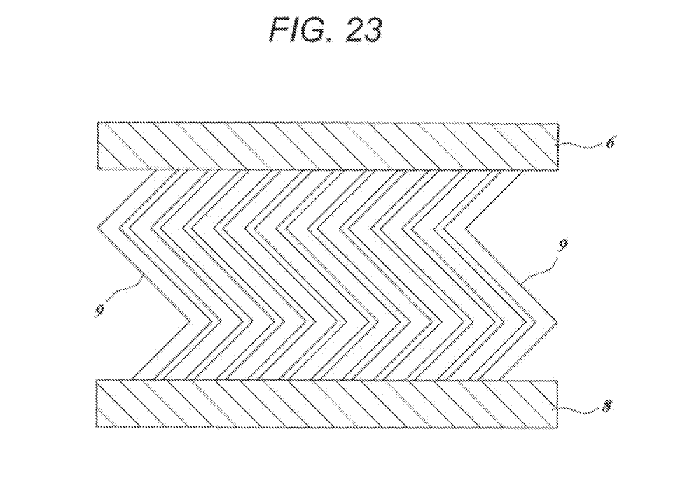

As illustrated in FIG. 23, a nano-structure layer 7 according to this embodiment has a structure in which nano-structures 9 having different inclinations for a top surface of a plate layer 8 and having zigzag shapes are two-dimensionally arranged. The nano-structure layer 7 having the nano-structures 9 of the above shapes can be manufactured by a next method.

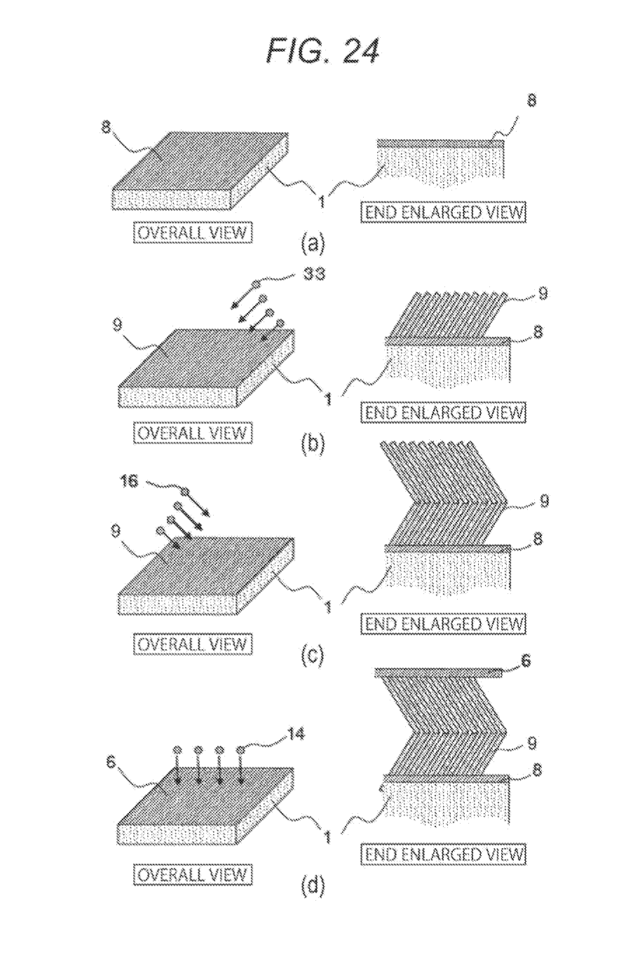

First, as illustrated in FIG. 24(a), a semiconductor chip 1 of which a top surface is provided with the plate layer 8 is prepared. Next, as illustrated in FIG. 24(b), copper atoms 33 are deposited from a direction oblique to a top surface of the plate layer 8, under an approximately vacuum environment. At this time, the atoms 33 are deposited without rotating the semiconductor chip 1, similar to the seventh embodiment.

Next, as illustrated in FIG. 24(c), the semiconductor chip 1 is rotated by 180° and the copper atoms 33 are deposited from the oblique direction according to the same sequence as the above case. Then, as illustrated in FIG. 24(c), nickel atoms 34 are deposited from the upper side of the nano-structure layer 7, so that the plate layer 6 is formed on an upper portion of the nano-structure layer 7.

Here, the semiconductor chip 1 is rotated only once. However, work illustrated in FIG. 24(b) and work illustrated in FIG. 24(c) are repeated by the necessary number of times, so that the zigzag shapes of the nano-structures 9 can be controlled.

According to the manufacturing method according to this embodiment, when the atoms 33 constituting the nano-structures 9 are deposited, the semiconductor chip 1 does not need to be rotated at all times. In addition, the problem according to the seventh embodiment in that the nano-structures 9 are not formed in the part of the top surface of the plate layer 8 or the part of the bottom surface of the plate layer 6 can be resolved. In addition, because volume occupancy of the nano-structures 9 can be increased as compared with the nano-structure layers 7 according to the first to fifth embodiments, thermal resistance or electrical resistance of the nano-structure layer 7 can be further decreased.

### Ninth Embodiment

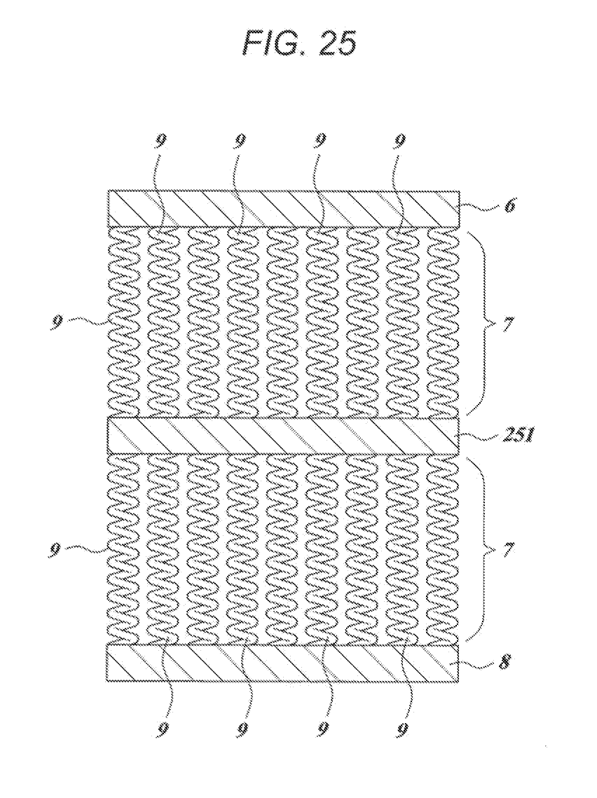

As illustrated in FIG. 25, a semiconductor device according to this embodiment is characterized in that a plurality of nano-structure layers 7 are laminated with an intermediate plate layer 251 therebetween. FIG. 25 illustrates an example of the case in which the nano-structure layers 7 of two layers are laminated. However, formation of the nano-structure layer 7 and formation of the intermediate plate layer 25 may be alternately repeated to laminate the nano-structure layers 7 of three layers or more. In addition, shapes of nano-structures 9 are not limited to the spring shapes and the nano-structures 9 may be the nano-structures 9 according to the sixth to eighth embodiments.

In the case in which the nano-structure layers 7 according to this embodiment are laminated in n steps, because deformation absorbed by each nano-structure layer 7 is decreased to 1/n, larger deformation can be absorbed. Meanwhile, because entire thermal resistance or electrical resistance of the nano-structure layer 7 becomes n times, it is desirable to select the number of nano-structure layers 7 laminated according to required deformation absorption ability, thermal resistance, and electrical resistance.

### Tenth Embodiment

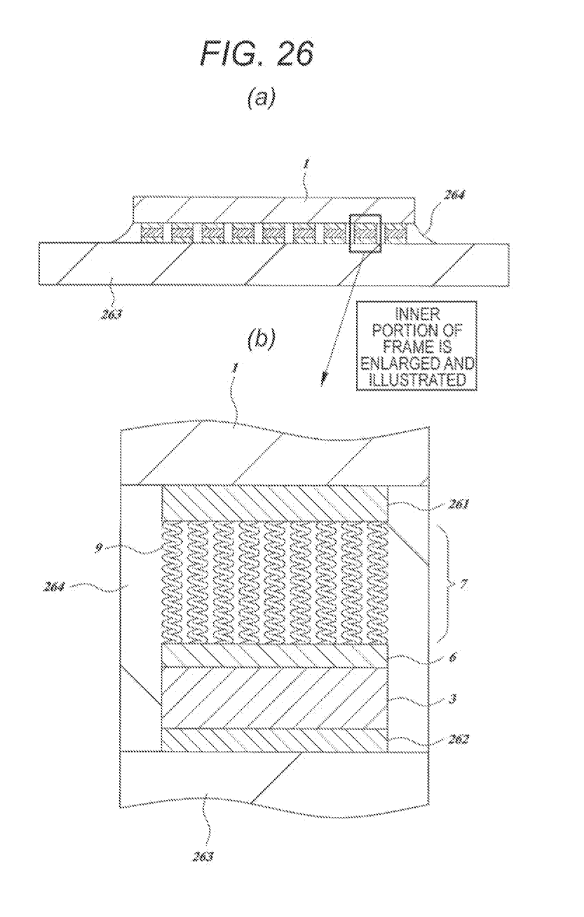

As illustrated in FIGS. 26(a) and 26(b), a semiconductor device according to this embodiment has a structure in which a semiconductor chip 1 is flip-chip bonded to a surface of a package substrate 263 functioning as a substrate and each of a plurality of flip-chip bonding portions to electrically connect the package substrate 263 and the semiconductor chip 1 includes a nano-structure layer 7. The nano-structure layer 7 is formed by two-dimensionally arranging a plurality of structures made of a conductive material.

A plurality of chip-side lands 261 are provided on a surface (in the drawing, a bottom surface) of the semiconductor chip 1. In addition, in a region facing the chip-side lands 261 in a top surface of the package substrate 263, a plurality of substrate-side lands 262 are provided. In addition, the nano-structure layer 7, a plate layer 6, and a joining layer are provided between the chip-side lands 261 and the substrate-side lands 262. In addition, an underfill resin 264 to seal the plurality of flip-chip bonding portions is filled into gaps of the plurality of flip-chip bonding portions. The nano-structure layer 7 is formed by two-dimensionally arranging the plurality of nano-structures 9 having spring shapes densely.

According to this embodiment, the nano-structure layer 7 is included in each of the plurality of flip-chip bonding portions, so that a thermal deformation difference of the semiconductor chip 1 and the package substrate 263 can be absorbed by the nano-structure layer 7. Therefore, a flip-chip-type semiconductor device having high reliability can be provided.

In addition, according to this embodiment, because the underfill resin 264 to seal the flip-chip bonding portions does not need to have a thermal deformation absorption function, a range of material choices of the underfill resin 264 is expanded. That is, because a material having ease of filling or high shock resistance at the time of sealing can be selected as the material of the underfill resin 264, a flip-chip-type semiconductor device having higher reliability can be provided. In addition, the underfill resin 264 may not be filled into the gaps of the flip-chip bonding portions by giving the thermal deformation absorption function to the nano-structure layer 7.

The invention accomplished by the inventors has been specifically described on the basis of the embodiments. However, it is needless to say that the present invention is not limited to the embodiments and various changes can be made without departing from the scope thereof.

### INDUSTRIAL APPLICABILITY

The present invention can be applied to reduction of thermal stress and improvement of heat radiation in a semiconductor device including a substrate and a semiconductor chip packaged on the substrate.

1. A semiconductor device comprising a substrate and a semiconductor chip packaged on the substrate,
wherein a structure layer formed by two-dimensionally arranging a plurality of structures having a cross-sectional shape of a diameter or a length of one side of less than 1 μm is provided between the semiconductor chip and the substrate.

2. The semiconductor device according to claim 1, wherein a first plate layer to which one end of each of the plurality of structures is connected is provided between the semiconductor chip and the structure layer and a second plate layer to which the other end of each of the plurality of structures is connected is provided between the substrate and the structure layer.

3. The semiconductor device according to claim 1, wherein each of the plurality of structures has a spring shape.

4. The semiconductor device according to claim 3, wherein, in each of the plurality of structures, external shapes of both ends are larger than an external shape of a center portion.

5. The semiconductor device according to claim 1, wherein each of the plurality of structures has a zigzag shape.

6. The semiconductor device according to claim 2, wherein each of the plurality of structures extends in a direction oblique to surfaces which the first plate layer and the second plate layer face.

7. The semiconductor device according to claim 2, wherein each of the plurality of structures extends in a direction vertical to surfaces which the first plate layer and the second plate layer face.

8. The semiconductor device according to claim 2, wherein the structure layers are laminated in multiple steps with one or more intermediate plate layers arranged between the first plate layer and the second plate layer therebetween.

9. A semiconductor device comprising a substrate and a semiconductor chip packaged on the substrate,
wherein the semiconductor chip is packaged on a top surface of the substrate in a state in which a back surface opposite to a principal surface thereof faces the top surface of the substrate,
one or more terminals electrically connected to elements formed in the semiconductor chip are formed in the principal surface of the semiconductor chip,
a conductive joining member is electrically connected to the terminals, and
a structure layer formed by two-dimensionally arranging a plurality of structures having a cross-sectional shape of a diameter or a length of one side of less than 1 μm is provided between the terminals and the joining member.

10. The semiconductor device according to claim 9, wherein a plurality of terminals including at least a gate terminal are formed in the principal surface of the semiconductor chip and a height of the joining member electrically connected to the gate terminal is larger than a diameter or a length of one side of the gate terminal.

11. The semiconductor device according to claim 10, wherein a position where the height of the joining member electrically connected to the gate terminal is maximized is in an upper portion of the semiconductor chip.

12. A semiconductor device comprising a base member, a substrate packaged on the base member, and a semiconductor chip packaged on the substrate,
wherein a structure layer formed by two-dimensionally arranging a plurality of structures made of an insulating material and having a cross-sectional shape of a diameter or a length of one side of less than 1 μm is provided between the base member and the substrate.

13. A semiconductor device comprising a substrate and a semiconductor chip packaged on the substrate,
wherein the semiconductor chip is flip-chip bonded to an upper portion of the substrate through a plurality of flip-chip bonding portions, and
each of the plurality of flip-chip bonding portions includes a structure layer formed by two-dimensionally arranging a plurality of structures made of a conductive material and having a cross-sectional shape of a diameter or a length of one side of less than 1 μm.

14. A semiconductor device, comprising:
a semiconductor chip which has a principal surface and a back surface opposite to the principal surface,
wherein a structure layer formed by two-dimensionally arranging a plurality of structures having a cross-sectional shape of a diameter or a length of one side of less than 1 μm is provided on the principal surface of the semiconductor chip.

15. A method of manufacturing a semiconductor device which includes a substrate and a semiconductor chip packaged on the substrate and in which a structure layer formed by two-dimensionally arranging a plurality of structures having a cross-sectional shape of a diameter or a length of one side of less than 1 μm is provided between the semiconductor chip and the substrate, comprising:
a process of radiating atoms from a direction oblique to a surface of the semiconductor chip and depositing the atoms to form the plurality of structures.

16. The method according to claim 15, wherein, when the plurality of structures are formed, the semiconductor chip is rotated about an axis vertical to a surface thereof to make each of the plurality of structures have a spring shape.
